(19) United States
(12) Patent Application Publication
(10) Pub. No.: US 2025/0040123 A1
(43) Pub. Date: Jan. 30, 2025

(54) SEMICONDUCTOR DEVICE HAVING LANDING PAD STRUCTURE

(71) Applicant: Samsung Electronics Co., Ltd., Suwon-si (KR)

(72) Inventors: Jongmin KIM, Suwon-si (KR); Seungbo KO, Suwon-si (KR); Kiseok LEE, Suwon-si (KR)

(73) Assignee: Samsung Electronics Co., Ltd., Suwon-si (KR)

(21) Appl. No.: 18/665,984

(22) Filed: May 16, 2024

(30) Foreign Application Priority Data
Jul. 25, 2023 (KR) 10-2023-0096640

(51) Int. Cl. H10B 12/00

(52) U.S. Cl. CPC H10B 12/315; H10B 12/0335; H10B 12/34; H10B 12/482; H10B 12/485

(57) ABSTRACT

A semiconductor device includes a substrate having an active region, a gate structure on the substrate, the gate structure extending across the active region in a first horizontal direction, bit line structures on bit line trenches extending in a second horizontal direction, intersecting the first horizontal direction, the bit line trenches on an upper surface of the substrate across the gate structure, contact plugs between the bit line structures, landing pad structures on the contact plugs, and an insulating pattern between the landing pad structures, the insulating pattern in contact with the bit line structures. Portions of the bit line structures extend in the second horizontal direction in the bit line trenches. Each of the landing pad structures includes a lower landing pad, arranged on a level lower than that of each of upper surfaces of the bit line structures, and an upper landing pad on the lower landing pad.

### CROSS-REFERENCE TO RELATED APPLICATION(S)

This application claims benefit of priority to Korean Patent Application No. 10-2023-0096640 filed on Jul. 25, 2023 in the Korean Intellectual Property Office, the disclosure of which is incorporated herein by reference in its entirety.

### BACKGROUND

The present inventive concepts relate to a semiconductor device having a landing pad structure.

As demand for implementation of high performance, high speed, and/or multi-functionalization of semiconductor devices increases, a degree of integration of semiconductor devices has been increasing. In manufacturing semiconductor devices having a fine pattern corresponding to the trend for a high degree of integration of semiconductor devices, it is necessary (or beneficial) to implement patterns having a fine width or a fine separation distance.

### SUMMARY

Various example embodiments provide a semiconductor device having a landing pad structure including a lower landing pad, lower than an upper surface of the bit line structure, and an upper landing pad, higher than the upper surface of the bit line structure.

In some example embodiments, there is provided a semiconductor device including a substrate having an active region, a gate structure on the substrate, the gate structure extending across the active region in a first horizontal direction, bit line structures on bit line trenches extending in a second horizontal direction, intersecting the first horizontal direction, the bit line trenches on an upper surface of the substrate across the gate structure, contact plugs between the bit line structures, landing pad structures on the contact plugs, and an insulating pattern between the landing pad structures, the insulating pattern in contact with the bit line structures. Portions of the bit line structures may extend in the second horizontal direction in the bit line trenches. Each of the landing pad structures may include a lower landing pad, arranged on a level lower than that of each of upper surfaces of the bit line structures, and an upper landing pad on the lower landing pad.

In some example embodiments, there is provided a semiconductor device including a substrate having active regions, gate structures on the substrate, the gate structures extending across the active regions in a first horizontal direction, bit line structures extending across the gate structures in a second horizontal direction, intersecting the first horizontal direction, a contact plug between the bit line structures, a landing pad structure on the contact plug, and an insulating pattern in contact with the bit line structures and the landing pad structure. A central portion of each of the active regions may vertically overlap one of the gate structures. A first end of each of the active regions may vertically overlap one of the bit line structures, and a second end of each of the active regions, opposite to the first end with respect to the central portion, may vertically overlap the contact plug. The landing pad structure may include a lower landing pad, arranged on a level lower than that of each of upper surfaces of the bit line structures, and an upper landing pad on the lower landing pad.

In some example embodiments, there is provided a semiconductor device including a substrate having active regions including a first end and a second end, a gate structure on the substrate, the gate structure extending across the active region in a first horizontal direction, bit line structures on bit line trenches extending in a second horizontal direction, intersecting the first horizontal direction, the bit line trenches on the first ends across the gate structure, spacer structures on side surfaces of the bit line structures, contact plugs between the bit line structures, the contact plugs in contact with side surfaces of the spacer structures and lower surfaces of the second ends, a metal-semiconductor compound layer on the contact plugs, landing pad structures on the metal-semiconductor compound layer, an insulating pattern between the landing pad structures, the insulating pattern in contact with the bit line structures, and a capacitor structure on the landing pad structures and the insulating pattern, the capacitor structure electrically connected to the landing pad structures. Portions of the bit line structures may extend in the second horizontal direction in the bit line trenches. Each of the landing pad structures may include a lower landing pad, arranged on a level lower than each of upper surfaces of the bit line structures, and an upper landing pad on the lower landing pad.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view of a semiconductor device according to an example embodiment;

FIG. 2A is vertical cross-sectional views of the semiconductor device illustrated in FIG. 1, taken along lines II-I′ and II-II′;

FIG. 2B is a vertical cross-sectional view of the semiconductor device illustrated in FIG. 1, taken along the line III-III′;

FIG. 3 is an enlarged view of a portion of the semiconductor device illustrated in FIG. 2A;

FIGS. 4 to 14 are plan views and vertical cross-sectional views sequentially illustrating processes of a method of manufacturing a semiconductor device according to an example embodiment;

FIG. 15 is a vertical cross-sectional view of a semiconductor device according to an example embodiment;

FIG. 16 is an enlarged view of a portion of the semiconductor device illustrated in FIG. 15; and

FIG. 17 is a vertical cross-sectional view of a semiconductor device according to an example embodiment.

### DETAILED DESCRIPTION

Hereinafter, various example embodiments of the present inventive concepts will be described below with reference to the accompanying drawings.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

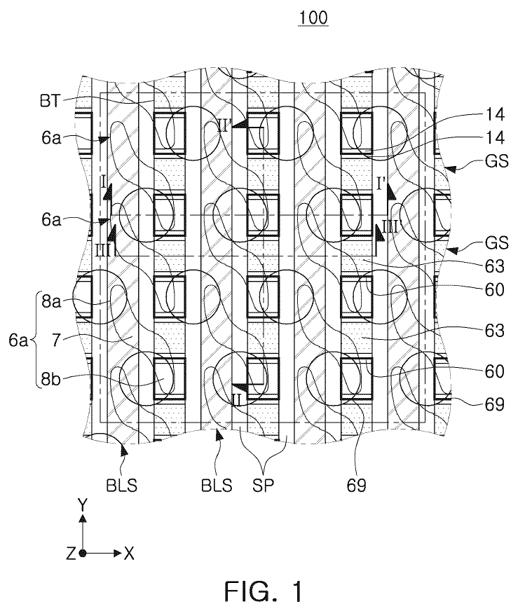

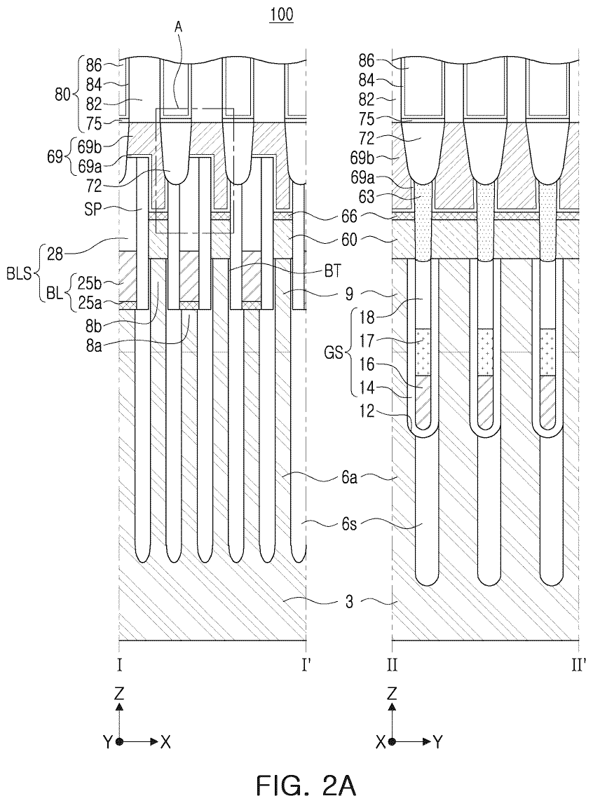

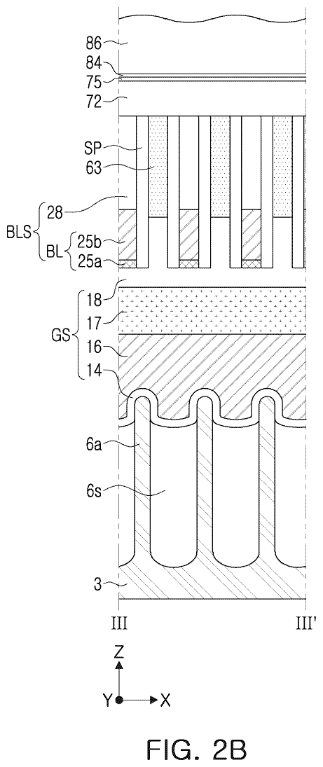

FIG. 1 is a plan view of a semiconductor device according to an example embodiment. FIG. 2A is vertical cross-sectional views of the semiconductor device illustrated in FIG. 1, taken along lines II-I′ and II-II′. FIG. 2B is a vertical cross-sectional view of the semiconductor device illustrated in FIG. 1, taken along the line III-III′.

Referring to FIGS. 1, 2A, and 2B, a semiconductor device 100 according to an example embodiment of the present inventive concepts may include a gate structure GS, a bit line structure BLS, a spacer structure SP, a contact plug 60, a landing pad structure 69, an insulating pattern 72, and a capacitor structure 80. For example, the semiconductor device 100 may be applied to a dynamic random access memory (DRAM) cell array, but the present inventive concepts are not limited thereto.

A substrate 3 may include a semiconductor material, such as a Group IV semiconductor, a Group III-V compound semiconductor, or a Group II-VI compound semiconductor. For example, the Group IV semiconductor may include silicon, germanium or silicon-germanium. The substrate 3 may be a silicon substrate, a silicon on insulator (SOI) substrate, a germanium substrate, a germanium on insulator (GOI) substrate, a silicon-germanium substrate, or a substrate including an epitaxial layer, but example embodiments are not limited thereto.

The substrate 3 may include an active region 6a, a device isolation layer 6s, and an impurity region 9. The device isolation layer 6s may be an insulating layer downwardly extending from an upper surface of the substrate 3, and may define the active region 6a. For example, the active region 6a may correspond to a portion of the upper surface of the substrate 3 surrounded by the device isolation layer 6s. In the plan view, the active regions 6a may extend in a horizontal direction between an X-direction and a Y-direction, and may have an S-shape, for example. However, the active region 6a disclosed herein is exemplary, and active regions 6a having various shapes may be implemented. In the plan view, a portion of the active region 6a, overlapping the gate structure GS, may be referred to as a central portion 7, and both ends of the active region 6a, disposed on both sides of the central portion 7, may be referred to as a first end 8a and a second end 8b. The active regions 6a may be spaced apart from each other in the X-direction and the Y-direction. For example, the center portions 7 of the active regions 6a may be spaced apart from each other in a lattice structure having regular intervals in the X-direction and the Y-direction, respectively.

The active region 6a may have impurity regions 9 extending from the upper surface of the substrate 3 to a predetermined (or desired) depth. The impurity regions 9 may serve as source/drain regions of a transistor. For example, each active region 6a may vertically overlap one gate structure GS, and the gate structures GS may cross the central portion 7 of the active region 6a. A source region and a drain region of the active region 6a may be formed on both sides of the gate structure GS. For example, the impurity region 9, positioned at the first end 8a, may correspond to the source region, and the impurity region 9, positioned at the second end 8b, may correspond to the drain region. The source region and the drain region may be formed by impurity regions 9 caused by doping or ion implantation of substantially the same impurities, and may be interchangeably referred to depending on a circuit configuration of a finally (or completely) formed transistor. The impurity regions 9 may include impurities having a conductivity type opposite to that of the substrate 101. For example, the substrate 3 may include P-type impurities, and the impurity regions 9 may include N-type impurities.

The device isolation layer 6s may include silicon oxide, silicon nitride, silicon oxynitride, or combinations thereof, and may be formed of a single layer or a plurality of layers.

The gate structures GS may extend in the X-direction, and may be spaced apart from each other in the Y-direction. As described above, the gate structures GS may cross the central portion 7 of the active region 6a. Transistors, respectively including the gate structure GS and the impurity regions 9, may form a buried channel array transistor (BCAT), but the present inventive concepts are not limited thereto.

In the cross-sectional view, the gate structures GS may be buried in the substrate 3, and for example, the gate structures GS may be disposed within a gate trench 12 formed in the substrate 3. The gate structure GS may include a gate dielectric layer 14, a first gate electrode 16, a second gate electrode 17, and a gate capping layer 18 disposed within the gate trench 12. The gate dielectric layer 14 may be conformally formed on an inner wall of the gate trench 12. The first gate electrode 16 may be disposed in a lower portion of the gate trench 12, and the second gate electrode 17 may be disposed on the first gate electrode 16. A gate capping layer 18 may be disposed on an upper portion of the gate structure GS and may fill the gate trench 12.

The gate dielectric layer 14 may include silicon oxide or a high-κ dielectric material. In example embodiments, the gate dielectric layer 14 may be a layer formed by oxidation of the active region 6a or a layer formed by deposition. The first gate electrode 16 may include at least one of titanium (Ti), titanium nitride (TiN), tantalum (Ta), tantalum nitride (TaN), tungsten (W), tungsten nitride (WN), and aluminum (Al). The second gate electrode 17 may include a material different from that of the first gate electrode 16. The second gate electrode 17 may include a doped semiconductor material. The doped semiconductor material may include, for example, silicon (Si) or silicon germanium (SiGe). The doped semiconductor material may include, for example, polysilicon containing impurities. The impurities may include an N-type impurity such as phosphorus (P) or arsenic (As). The gate capping layer 18 may include silicon nitride.

The bit line structures BLS may extend in the Y-direction, and may be spaced apart from each other in the X-direction. The bit line structures BLS may be disposed on bit line trenches BT, extending in the Y-direction. The bit line trench BT may be formed on the upper surface of the substrate 3, and may expose an upper surface of the first end 8a of the active region 6a. In the plan view, the bit line structures BLS may vertically overlap the first ends 8a of the active regions 6a. In the cross-sectional view, a lower surface of the bit line structure BLS may be positioned on a level lower than that of an upper surface of the active region 6a. For example, a lower portion of the bit line structure BLS may be buried in the gate capping layer 18. A portion of the gate capping layer 18 may upwardly protrude between the bit line structures BLS.

The bit line structure BLS may have a bar shape, extending in the Y-direction. The bit line structure BLS may include a bit line BL and a bit line capping layer 28 on the bit line BL. The bit line BL may include a first conductive layer 25a and a second conductive layer 25b being sequentially stacked. The first conductive layer 25a may include a metal-semiconductor compound. The metal-semiconductor compound may be, for example, a layer obtained by silicidizing a portion of the first conductive layer 25a. For example, the metal-semiconductor compound may include cobalt silicide (CoSi), titanium silicide (TiSi), nickel silicide (NiSi), tungsten silicide (WSi), or other metal silicides, or may include a nitride such as TiSiN. The second conductive layer 25b may include a metal material such as titanium (Ti), tantalum (Ta), tungsten (W), or aluminum (Al). The first conductive layer 25a may be in contact with the upper surface of the first end 8a of the active region 6a. The second conductive layer 25b may be electrically connected to the active region 6a through the first conductive layer 25a.

In an example embodiment, the first conductive layer 25a may cover the gate structure GS and the first ends 8a of the active region 6a in the bit line trench BT, and may extend in the Y-direction. In an example embodiment, the first conductive layers 25a may be disposed on the first end 8a of the active region 6a, and may be spaced apart from each other in the Y-direction. A lower portion of the second conductive layer 25b may extend in the Y-direction in the bit line trench BT.

The bit line capping layer 28 may be disposed on the second conductive layer 25b. A side surface of the bit line capping layer 28 may be coplanar with the first conductive layer 25a and the second conductive layer 25b. The bit line capping layer 28 may include silicon oxide, silicon nitride, silicon oxynitride, or combinations thereof, for example, silicon nitride.

The spacer structures SP may be respectively disposed on both side surfaces of the bit line structures BLS, and may extend in the Y-direction along side surfaces of the bit line structures BLS. A lower portion of the spacer structure SP may extend in the Y-direction in the bit line trench BT. The spacer structure SP may be formed of a single layer or a plurality of layers. The spacer structure SP may include silicon oxide, silicon nitride, silicon oxynitride, or combinations thereof. The spacer structure SP according to the present inventive concepts is exemplary, and the material of the spacer structure SP and the number of layers of the spacer structure SP are not limited thereto, and may be changed in various manners.

The contact plug 60 is disposed between the bit line structures BLS, and may be in contact with the spacer structures SP. In the plan view, the contact plugs 60 may vertically overlap the second end 8b of the active region 6a, and may be disposed between the bit line structures BLS and between the gate structures GS. An upper surface of the contact plug 60 may be positioned on a level lower than that of an upper surface of the bit line structure BLS. A distance between the contact plugs 60, adjacent to each other in the X-direction, may be equal to a horizontal width of the bit line structure BLS, disposed therebetween, and a horizontal width of the spacer structure SP, disposed on both sides of the bit line structure BLS. According to an example embodiment of the present inventive concepts, the adjacent contact plugs 60 may be spaced apart from each other by the bit line structure BLS and the spacer structure SP, thereby preventing and/or reducing electrical bridging between the contact plugs 60.

The contact plug 60 may be in contact with the impurity region 9 of the active region 6a, and may be electrically connected to the active region 6a. The contact plug 60 may be formed of a conductive material, for example, at least one of polysilicon (Si), titanium (Ti), titanium nitride (TiN), tantalum (Ta), tantalum nitride (TaN), tungsten (W), tungsten nitride (WN), and aluminum (Al). In an example embodiment, the contact plug 60 may include doped polysilicon, and may include N-type impurities such as phosphorus (P), arsenic (As), and antimony (Sb).

The semiconductor device 100 may further include a fence structure 63 disposed between the bit line structures BLS. In the plan view, the fence structures 63 may overlap the gate structures GS in a vertical direction, and may be disposed alternately with the contact plugs 60 in the Y-direction. The fence structures 63 may spatially isolate the contact plugs 60 from each other, and may electrically insulate the contact plugs 60 from each other. The fence structure 63 may have a bar shape or columnar shape, extending in the vertical direction. A lower surface of the fence structure 63 may be in contact with the gate capping layer 18 of the gate structure GS. The fence structure 63 may include an insulating material, for example silicon nitride.

The semiconductor device 100 may further include a metal-semiconductor compound layer 66, disposed on the upper surface of the contact plug 60. The metal-semiconductor compound layer 66 may be in contact with a side surface of the spacer structure SP. The metal-semiconductor compound layer 66 may be formed by silicidizing a portion of the contact plug 60 including polysilicon. The metal-semiconductor compound layer 66 may include cobalt silicide (CoSi), titanium silicide (TiSi), nickel silicide (NiSi), tungsten silicide (WSi), or other metal silicides.

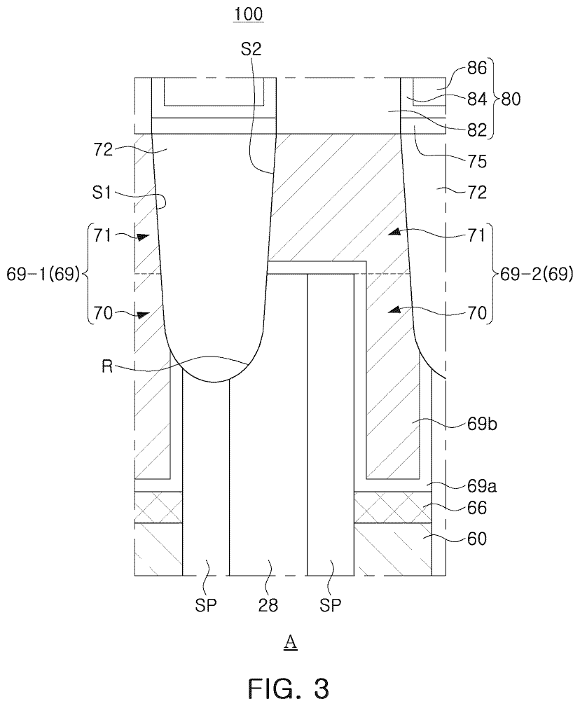

FIG. 3 is an enlarged view of a portion of the semiconductor device illustrated in FIG. 2A. FIG. 3 may correspond to region A.

Referring to FIGS. 1 to 3, the landing pad structure 69 may be disposed on the metal-semiconductor compound layer 66. The landing pad structure 69 may be electrically connected to the active region 6a through the contact plug 60. The landing pad structure 69 may include a barrier layer 69a and a metal layer 69b on the barrier layer 69a. The barrier layer 69a may be conformally formed along an upper surface of the metal-semiconductor compound layer 66, a side surface of the spacer structure SP, and an upper surface of the bit line structure BLS. The metal layer 69b may be disposed on the barrier layer 69a, and may fill a space between the bit line structures BLS. The barrier layer 69a may include at least one of a metal nitride, for example, titanium nitride (TiN), tantalum nitride (TaN), and tungsten nitride (WN). The metal layer 69b may include a conductive material, for example, at least one of titanium (Ti), tantalum (Ta), tungsten (W), molybdenum (Mo), ruthenium (Ru), and aluminum (Al).

The landing pad structure 69 may include a lower landing pad 70 and an upper landing pad 71. A portion of the landing pad structure 69, positioned on a level lower than that of an upper surface of the bit line structure BLS, may be referred to as a lower landing pad 70, and a portion of the landing pad structure 69, positioned on a level higher than that of the upper surface of the bit line structure BLS, may be referred to as an upper landing pad 71. The lower landing pad 70 and the upper landing pad 71 may include the same material and may be integrally formed.

A horizontal width or a maximum (or desired) horizontal width of the lower landing pad 70 may be equal to a distance between adjacent spacer structures SP. The horizontal width or a maximum (or desired) horizontal width of the lower landing pad 70 may also be equal to a horizontal width of the contact plug 60. A distance between the adjacent lower landing pads 70 in an X-direction may be equal to a horizontal width of the bit line structure BLS, disposed therebetween, and a horizontal width of the spacer structure SP, disposed on both sides of the bit line structure BLS. According to an example embodiment of the present inventive concepts, the adjacent lower landing pads 70 may be spaced apart from each other by the bit line structure BLS and the spacer structure SP, thereby preventing and/or reducing electrical bridging between the lower landing pads 70.

The upper landing pad 71 may be disposed on the lower landing pad 70. A horizontal width of the upper landing pad 71 may be wider than a horizontal width of the lower landing pad 70. For example, the upper landing pad 71 may extend further in a horizontal direction than the lower landing pad 70, and may be in contact with the upper surface of the bit line structure BLS and an upper surface of the spacer structure SP. The horizontal width of the upper landing pad 71 may upwardly decrease. A distance between adjacent upper landing pads 71 may be equal to as a horizontal width of the insulating pattern 72.

The insulating pattern 72 may be disposed between the landing pad structures 69. The insulating pattern 72 may spatially isolate the landing pad structures 69 from each other, and may electrically insulate the landing pad structures 69 from each other. An upper surface of the insulating pattern 72 may be coplanar with the upper landing pad 71, and a lower end of the insulating pattern 72 may be positioned on a level lower than that of the upper surface of the bit line structure BLS. For example, upper portions of the bit line structure BLS and the spacer structure SP may have a recess, and the insulating pattern 72 may fill the recess. A horizontal width of the insulating pattern 72 may upwardly increase. The insulating pattern 72 may include silicon oxide, silicon nitride, silicon oxynitride, or combinations thereof. For example, the insulating pattern 72 may include silicon nitride.

In the cross-sectional view of FIG. 3, the landing pad structures 69, disposed on both sides of the insulating pattern 72, may be referred to as a first landing pad structure 69-1 and a second landing pad structure 69-2, respectively. The insulating pattern 72 may have a first side surface and a second side surface, opposite to the first side surface. The first side surface of the insulating pattern 72 may be in contact with a first lower landing pad 70 and a first upper landing pad 71 of the first landing pad structure 69-1. The second side surface of the insulating pattern 72 may be in contact with a second upper landing pad 71 of the second landing pad structure 69-2. The second upper landing pad 71 may be spaced apart from the first upper landing pad 71 in the horizontal direction. The second upper landing pad 71 may be spaced apart from the first lower landing pad 70 in the horizontal direction and vertical direction. As illustrated in FIG. 3, according to example embodiments of the present inventive concepts, the insulating pattern 72 may electrically insulate the second upper landing pad 71 from the first landing pad structure 69-1, thereby preventing and/or reducing electrical bridging between adjacent landing pad structures 69.

The semiconductor device 100 may further include an etch stop layer 75, covering an upper surface of a structure of the insulating pattern 72. The capacitor structure 80 may be disposed on the landing pad structure 69 and the structure of the insulating pattern 72. The capacitor structure 80 may include a lower electrode 82, a capacitor dielectric layer 84, and an upper electrode 86. The lower electrode 82 may pass through the etch stop layer 75 to be in contact with an upper surface of the landing pad structure 69. The capacitor dielectric layer 84 may cover the lower electrode 82 and the etch stop layer 75, and the upper electrode 86 may cover the capacitor dielectric layer 84. The capacitor structure 80 may be electrically connected to the landing pad structure 69 and the contact plug 60.

The lower electrode 82 and the upper electrode 86 may include, for example, at least one of polycrystalline silicon, titanium nitride (TiN), tungsten (W), titanium (Ti), ruthenium (Ru), and tungsten nitride (WN). The capacitor dielectric layer 84 may include, for example, at least one of high-κ materials such as zirconium oxide (ZrO₂), aluminum oxide (Al₂O₃), and hafnium oxide (Hf₂O₃).

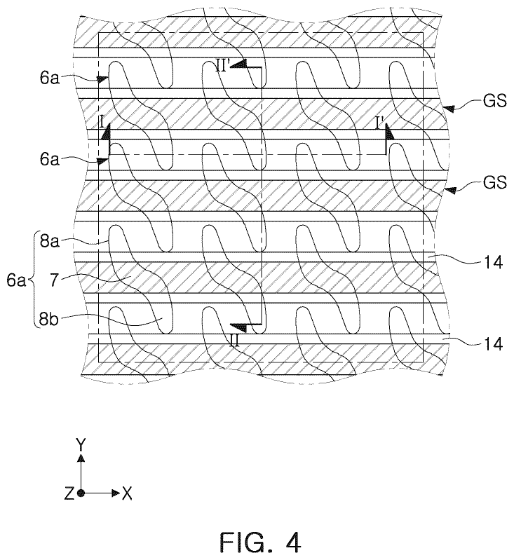

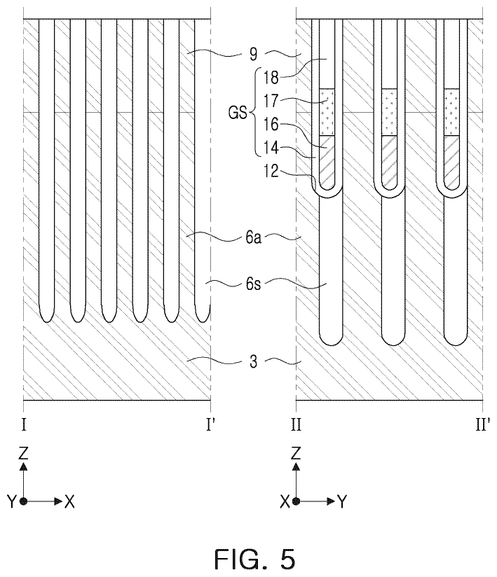

FIGS. 4 to 14 are plan views and vertical cross-sectional views sequentially illustrating processes of a method of manufacturing a semiconductor device according to an example embodiment. Specifically, FIGS. 4, 6, 8, 10, and 12 are plan views corresponding to FIG. 1. FIGS. 5, 7, 9, 11, 13, and 14 are vertical cross-sectional views corresponding to FIG. 2A.

Referring to FIGS. 4 and 5, a device isolation layer 6s and a gate structure GS may be formed in the substrate 3. The device isolation layer 6s may be formed by removing a portion of an upper surface of the substrate 3, filling a space in which the substrate 3 is removed with an insulating material, and planarizing the insulating material. The device isolation layer 6s may be formed of a single layer or a plurality of layers. In an example embodiment, the device isolation layer 6s may not have a constant depth.

The device isolation layer 6s may define active regions 6a. For example, the active regions 6a may correspond to portions of the upper surface of the substrate 3, surrounded by the device isolation layer 6s. In the plan view, the active regions 6a may extend in a horizontal direction between an X-direction and a Y-direction. However, the active region 6a disclosed herein is exemplary, and the active regions 6a, having various shapes, may be implemented. The active regions 6a may be spaced apart from each other in the X-direction and the Y-direction.

In an example embodiment, impurity regions 9 may be formed by implanting impurities into the substrate 3, before the device isolation layer 6s is formed. However, in some example embodiments, the impurity regions 9 may be formed after a device isolation layer 6s is formed or during another process operation.

Thereafter, the substrate 3 may be anisotropically etched to form gate trenches 12. The gate trenches 12 may extend in the X-direction, and may cross the active region 6a and the device isolation layer 6s. The gate structure GS may be formed by forming a gate dielectric layer 14, a first gate electrode 16, a second gate electrode 17, and a gate capping layer 18 in the gate trench 12. The gate dielectric layer 14 may be formed in the gate trench 12 by performing an oxidation process or a deposition process, and the gate dielectric layer 14 may be conformally formed on an inner wall of the gate trench 12.

The first gate electrode 16 may be formed by forming a conductive material on the gate dielectric layer 14 and then recessing the conductive material. The first gate electrode 16 may include a metal material such as tungsten (W). The second gate electrode 17 may be formed by depositing a semiconductor material, including impurities, on the first gate electrode 16. The semiconductor material may include, for example, polycrystalline silicon, and the impurities may include an N-type impurities such as phosphorus (P) or arsenic (As).

The gate capping layer 18 may be formed by forming an insulating material on the second gate electrode 17 to fill the gate trench 12 and then performing a planarization process. In an example embodiment, the gate trench 12 may be formed to be deeper in the device isolation layer 6s than in the active region 6a.

Each active region 6a may vertically overlap a corresponding one of the gate structures GS. For example, in the plan view, the gate trenches 12 may vertically overlap central portions 7 of the active regions 6a, and may extend in the X-direction. The gate structures GS may be spaced apart from each other in the Y-direction. Both ends of the active region 6a, not overlapping the gate structure GS, may be referred to as a first end 8a and a second end 8b. The second end 8b may be positioned to be opposite to the first end 8a with respect to the corresponding gate trench 12.

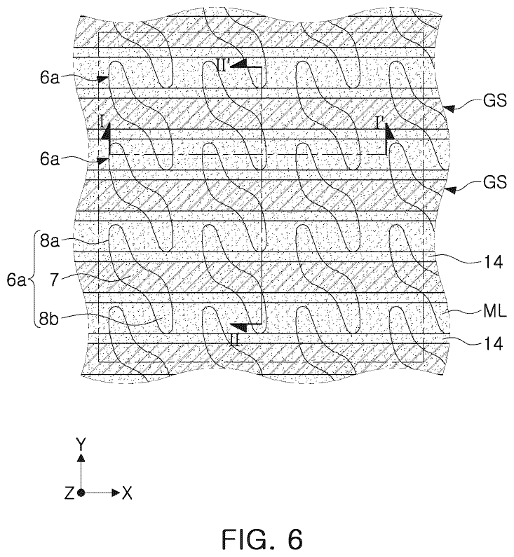

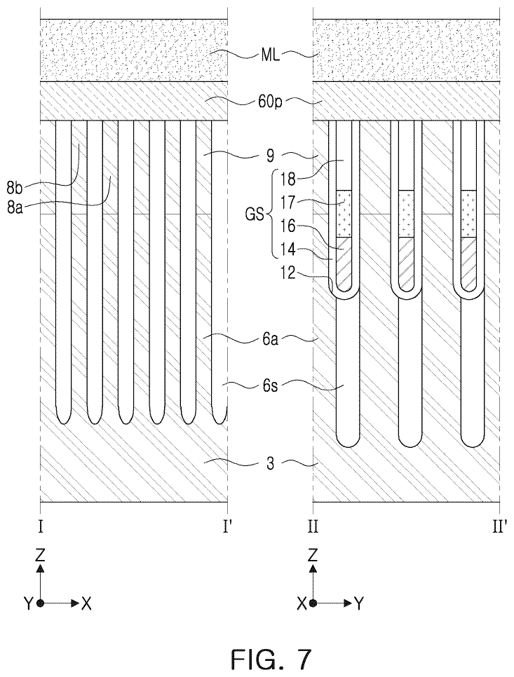

Referring to FIGS. 6 and 7, a conductive material layer 60p and a mold layer ML may be formed on the substrate 3. The conductive material layer 60p may cover upper surfaces of the active region 6a, the device isolation layer 6s, and the gate structure GS, and may extend in the horizontal direction. The mold layer ML may be formed on the conductive material layer 60p.

In an example embodiment, the conductive material layer 60p may include a doped semiconductor material. The doped semiconductor material may include, for example, silicon (Si) or silicon germanium (SiGe). The doped semiconductor material may include, for example, polysilicon containing impurities. The impurities may include N-type impurities such as phosphorus (P) or arsenic (As).

The mold layer ML may include an insulating material. The insulating material may include silicon oxide, silicon nitride, silicon oxycarbonitride, or combinations thereof.

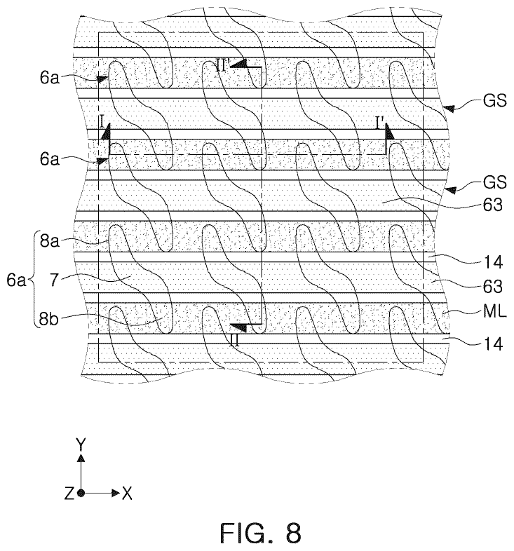

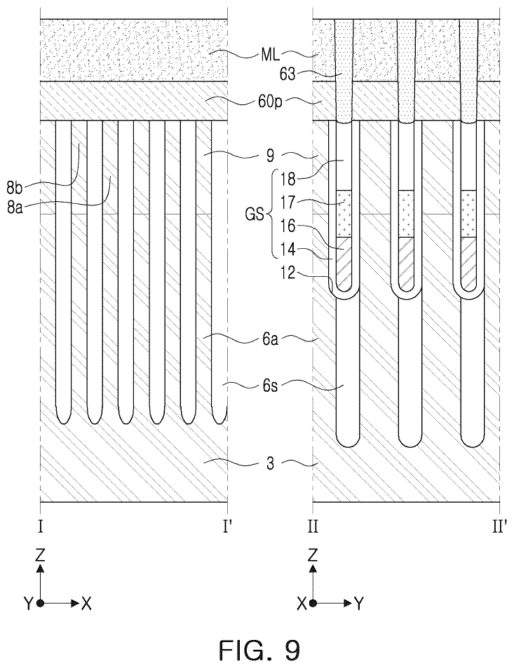

Referring to FIGS. 8 and 9, the fence structure 63 may be formed on the gate structure GS. The fence structure 63 may be formed by anisotropically etching a conductive material layer 60p and a mold layer ML to form a trench exposing an upper surface of the gate structure GS, forming an insulating material within the trench, and performing a planarization process on the insulating material. The fence structures 63 may extend on the gate structures GS in the X-direction, and may be spaced apart from each other in the Y-direction. For example, the fence structures 63 and the mold layers ML may be alternately disposed in the Y-direction.

The fence structure 63 may include silicon oxide, silicon nitride, silicon oxynitride, or combinations thereof. For example, the fence structure 63 may include silicon nitride.

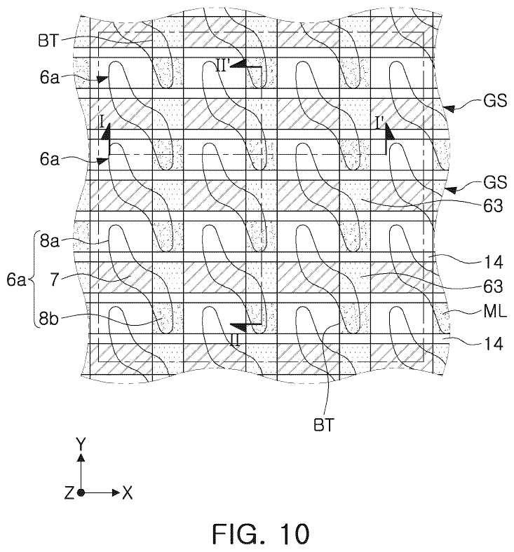

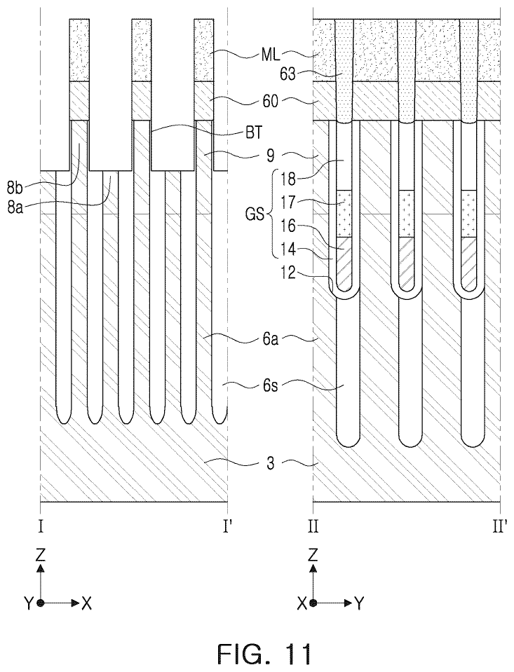

Referring to FIGS. 10 and 11, the conductive material layer 60p and the mold layer ML may be anisotropically etched to form the bit line trench BT, exposing the active regions 6a. The bit line trenches BT may extend in the Y-direction, and may be spaced apart from each other in the X-direction. When the bit line trench BT is formed, upper portions of the active region 6a and the device isolation layer 6s may be partially etched. For example, the bit line trench BT may expose a side surface of the upper portion of the device isolation layer 6s, and may expose a upper surface of the first end 8a of the active region 6a. The second end 8b may not be exposed by the bit line trench BT, and the upper surface of the first end 8a may be positioned on a level lower than that of an upper surface of the second end 8b.

When the bit line trench BT is formed, the conductive material layer 60p may be etched to form the contact plug 60. The contact plug 60 may be in contact with the upper surface of the second end 8b of the active region 6a. In addition, the contact plug 60 may be in contact with an upper surface of the device isolation layer 6s. The contact plugs 60 may be spaced apart from each other in the X-direction and the Y-direction. The contact plugs 60 may be disposed alternately with the fence structure 63 in the Y-direction.

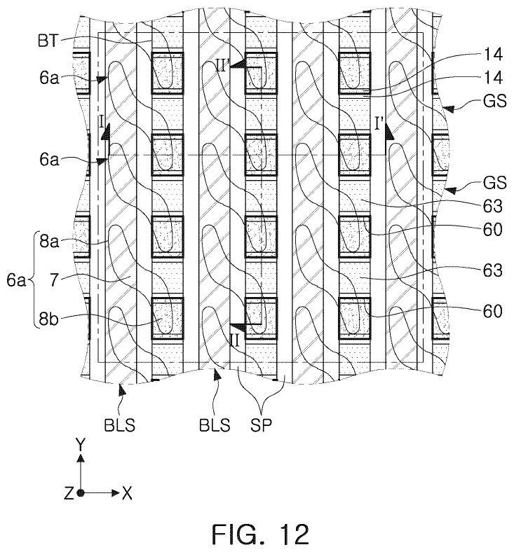

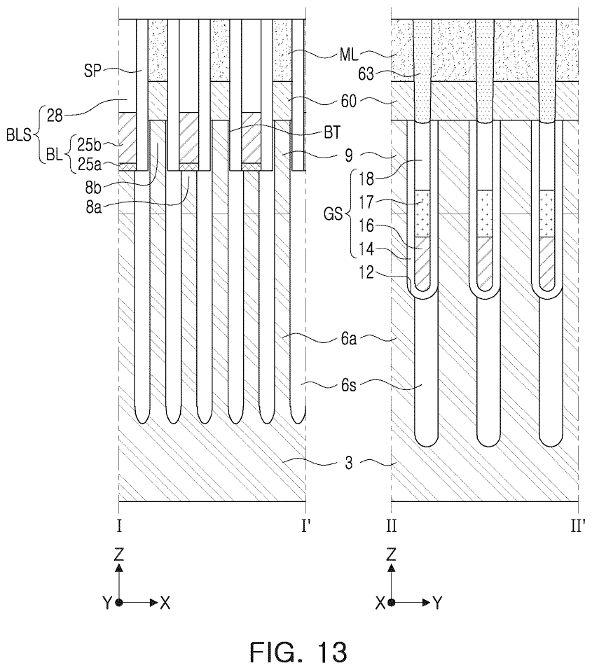

Referring to FIGS. 12 and 13, the spacer structure SP and the bit line structure BLS may be formed within the bit line trench BT. The spacer structure SP may be formed by depositing an insulating material to cover an inner wall of the bit line trench BT, the contact plug 60, and the mold layer ML, and performing an anisotropic etching process of etching the insulating material. The spacer structure SP may cover a side surface of the bit line trench BT, a side surface of the contact plug 60, and a side surface of the mold layer ML, but may not cover the first end 8a of the active region 6a. The spacer structure SP may be formed of a single layer or a plurality of layers. The spacer structure SP may extend in the Y-direction along the bit line trench BT.

After the spacer structure SP is formed, the first conductive layer 25a, the second conductive layer 25b, and the bit line capping layer 28 may be deposited in the bit line trench BT to form the bit line structure BLS. The first conductive layer 25a and the second conductive layer 25b may include a conductive material, and may form the bit line BL. The first conductive layer 25a may include a metal-semiconductor compound. The metal-semiconductor compound may be, for example, a layer obtained by silicidizing a portion of the active region 6a. For example, the metal-semiconductor compound may include cobalt silicide (CoSi), titanium silicide (TiSi), nickel silicide (NiSi), tungsten silicide (WSi), or other metal silicides. The second conductive layer 25b may include a metal material such as titanium (Ti), tantalum (Ta), tungsten (W), or aluminum (Al). The number of conductive patterns, forming the bit line BL, the type of material of the conductive patterns, and/or an order in which the conductive patterns are stacked may be changed in various manners in some example embodiments.

The bit line capping layer 28 may be disposed on the second conductive layer 25b, and may entirely fill the bit line trench BT. After the bit line capping layer 28 is formed, an etch-back process or a planarization process may be performed. Upper surfaces of the bit line capping layer 28, the spacer structure SP, and the mold layer ML may be coplanar with each other.

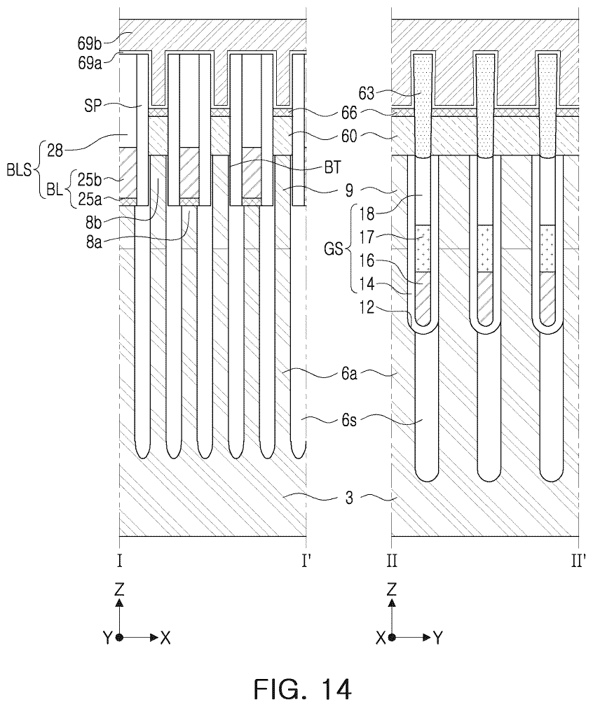

Referring to FIG. 14, the mold layer ML may be removed. The mold layer ML may include a material having an etch selectivity to that of the spacer structure SP, the bit line capping layer 28, and the fence structure 63, and may be selectively removed using a wet etching process. An upper surface of the contact plug 60 may be exposed by removing the mold layer ML.

A metal-semiconductor compound layer may be formed on the contact plug 60. The metal-semiconductor compound layer 66 may be, for example, a layer obtained by silicidizing a portion of the contact plug 60. For example, the metal-semiconductor compound layer 66 may include cobalt silicide (CoSi), titanium silicide (TiSi), nickel silicide (NiSi), tungsten silicide (WSi), or other metal silicides.

The barrier layer 69a and the metal layer 69b may be formed on the bit line structure BLS, the contact plug 60, and the fence structure 63. The barrier layer 69a may be conformally formed along the bit line structure BLS, the contact plug 60 and the fence structure 63. The metal layer 69b may be formed on the barrier layer 69a, and may fill a space between the bit line structures BLS and a space between the fence structures 63.

Referring back to FIGS. 1 to 3, the barrier layer 69a and the metal layer 69b may be patterned using an etching process to form the landing pad structure 69. In the etching process, portions of the bit line structure BLS and the spacer structure SP may be etched, and recesses may be formed in the upper portions of the bit line structure BLS and the spacer structure SP. After an insulating material is deposited to fill the recess and cover the metal layer 69b, the insulating material may be planarized to form the insulating pattern 72. The insulating patterns 72 may spatially isolate the landing pad structures 69 from each other, and may electrically insulate the landing pad structures 69 from each other. A horizontal width of the insulating pattern 72 may upwardly increase.

A portion of the landing pad structure 69, positioned on a level lower than that of the upper surface of the bit line structure BLS, may be referred to as a lower landing pad 70, and a portion of the landing pad structure 69, positioned on a level higher than that of the upper surface of the bit line structure BLS, may be referred to as an upper landing pad 71. Adjacent lower landing pads 70 may be spaced apart from each other by the bit line structure BLS and the spacer structure SP. Adjacent upper landing pads 71 may be spaced apart from each other by the spacer structure SP.

The semiconductor device 100 may be manufactured by forming the etch stop layer 75 and the capacitor structure 80 on the landing pad structure 69 and the insulating pattern 72. The etch stop layer 75 may be formed to cover upper surfaces of the landing pad structure 69 and the insulating pattern 72. The capacitor structure 80 may include a lower electrode 82, passing through the etch stop layer 75 to be connected to the landing pad structure 69 and the conductive pattern, a capacitor dielectric layer 84 on the lower electrode 82, and an upper electrode 86 on the capacitor dielectric layer 84.

FIGS. 6 to 9 illustrate that the fence structure 63 is formed in a space in which the conductive material layer 60p, a conductive material included in the contact plug 60, is formed and the conductive material layer 60p is partially removed. However, in some example embodiments, the contact plug 60 may be formed by forming an insulating material included in the fence structure 63 and then partially removing the insulating material and depositing a conductive material.

In some example embodiments, a process of forming the mold layer ML may be omitted in a process of manufacturing the semiconductor device 100. For example, the mold layer ML may not be formed after the process of forming the conductive material layer 60p described with reference to FIG. 7. After the process of forming the bit line structure BLS described with reference to FIG. 13, an upper portion of the conductive material layer 60p may be etched back such that a side surface of the fence structure 63 is exposed, thereby forming the contact plug 60.

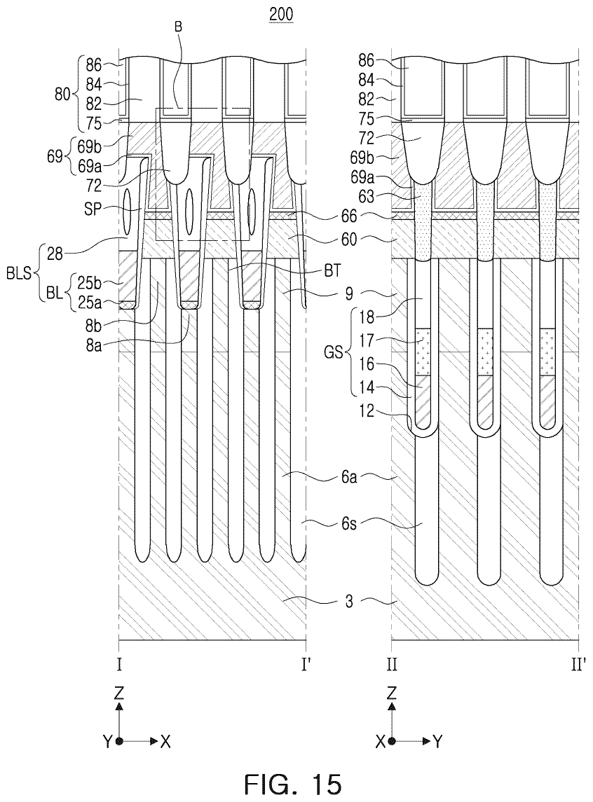

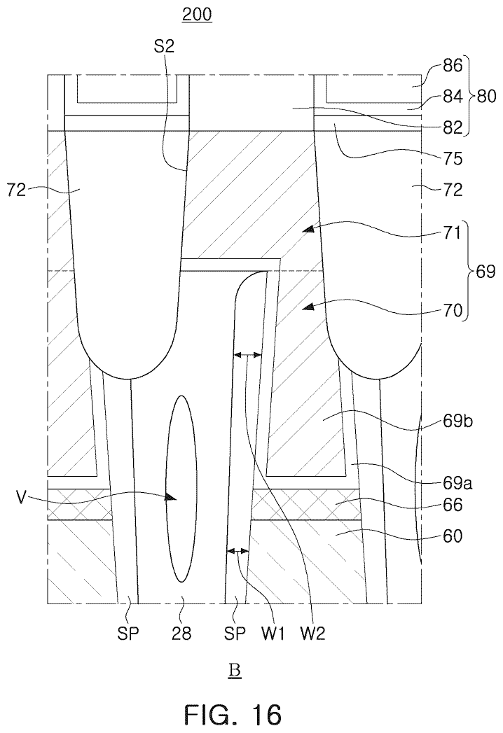

FIG. 15 is a vertical cross-sectional view of a semiconductor device according to an example embodiment. FIG. 16 is an enlarged view of a portion of the semiconductor device illustrated in FIG. 15. FIG. 16 may correspond to region B illustrated in FIG. 15.

Referring to FIGS. 15 and 16, a semiconductor device 200 may include bit line structures BLS crossing active region 6a, contact plugs 60 between the bit line structures BLS, and landing pad structures 69 on the contact plugs 60. In an example embodiment, a horizontal width of the bit line structure BLS may upwardly increase. For example, in the process of forming the bit line trench BT described with reference to FIG. 11, the bit line trench BT may have a tapered shape having a downwardly decreasing horizontal width. Horizontal widths of a first conductive layer 25a, a second conductive layer 25b, and a bit line capping layer 28 may upwardly increase. In an example embodiment, the bit line capping layer 28 may include a void therein.

In an example embodiment, a spacer structure SP may not have a constant horizontal width. For example, the spacer structure SP may have a first horizontal width W1 on a first vertical level, and the spacer structure SP may have a second horizontal width W2, wider than the first horizontal width W1, on a second vertical level higher than the first vertical level.

In an example embodiment, a horizontal width of a contact plug 60 may upwardly decrease.

The landing pad structure 69 may include a lower landing pad 70 and an upper landing pad 71. In an example embodiment, horizontal widths of the lower landing pad 70 and the upper landing pad 71 may upwardly decrease.

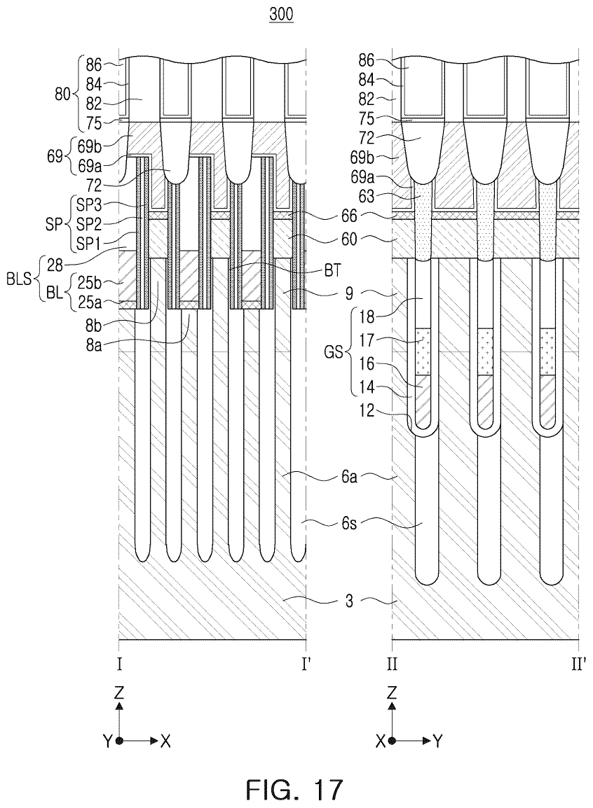

FIG. 17 is a vertical cross-sectional view of a semiconductor device according to an example embodiment.

Referring to FIG. 17, a semiconductor device 300 may include a spacer structure SP, disposed on a side surface of a bit line structure BLS. In an example embodiment, the spacer structure SP may include a first spacer SP1, a second spacer SP2, and a third spacer SP3. The first spacer SP1 may be in contact with side surfaces of a first conductive layer 25a, a second conductive layer 25b, and a bit line capping layer 28. The third spacer SP3 may be in contact with side surfaces of a contact plug 60 and a metal-semiconductor compound layer 66. The second spacer SP2 may be disposed between the first spacer and the third spacer.

In an example embodiment, the second spacer SP2 may include an air gap therein, and the first spacer SP1 and the third spacer SP3 may define the air gap. For example, a portion or all of the second spacer SP2 may be configured as an air gap. After the process of forming the barrier layer 69a and the metal layer 69b described with reference to FIG. 14, the barrier layer 69a and the metal layer 69b may be etched to expose an upper portion of the spacer structure SP. The spacer structure SP may include silicon oxide between the first spacer SP1 and the third spacer SP3. After the spacer structure SP is exposed, silicon oxide between the first spacer SP1 and the third spacer SP2 may be selectively etched to form an air gap. The first spacer SP1 and the third spacer SP3 may include silicon nitride.

According to some example embodiments of the present inventive concept, a landing pad structure may include a lower landing pad, lower than an upper surface of a bit line structure, and an upper landing pad, higher than the upper surface of the bit line structure. An upper surface of a contact plug may be lower than the upper surface of the bit line structure. An insulating pattern may fill a recess of the bit line structure, and may be disposed between the landing pad structures. Accordingly, the contact plugs and the landing pad structures may be spaced apart from each other by the bit line structure and the insulating pattern, thereby preventing and/or reducing electrical bridging between the contact plugs and the landing pad structures.

While various example embodiments have been shown and described above, it will be apparent to those skilled in the art that modifications and variations could be made without departing from the scope of the present inventive concepts as defined by the appended claims.

What is claimed is:

1. A semiconductor device comprising:
a substrate having an active region;
a gate structure on the substrate, the gate structure extending across the active region in a first horizontal direction;
bit line structures on bit line trenches extending in a second horizontal direction, intersecting the first horizontal direction, the bit line trenches on an upper surface of the substrate across the gate structure;
contact plugs between the bit line structures;
landing pad structures on the contact plugs; and
an insulating pattern between the landing pad structures, the insulating pattern in contact with the bit line structures, wherein
portions of the bit line structures extend in the second horizontal direction in the bit line trenches, and
each of the landing pad structures includes a lower landing pad, arranged on a level lower than that of each of upper surfaces of the bit line structures, and an upper landing pad on the lower landing pad.

2. The semiconductor device of claim 1, wherein
a horizontal width of each of the upper landing pads is wider than a horizontal width of each of the lower landing pads, and
lower surfaces of the upper landing pads overlap upper surfaces of the bit line structures in a vertical direction.

3. The semiconductor device of claim 1, wherein a horizontal width of each of the upper landing pads upwardly decreases.

4. The semiconductor device of claim 1, wherein
the lower landing pad does not overlap the bit line structures in a vertical direction, and
a portion of the upper landing pad overlaps the bit line structures in the vertical direction.

5. The semiconductor device of claim 1, wherein
the landing pad structures include a first landing pad structure and a second landing pad structure, adjacent to each other in the first horizontal direction, with the insulating pattern interposed therebetween,
a first side surface of the insulating pattern is in contact with a first lower landing pad and a first upper landing pad of the first landing pad structure, and
a second side surface of the insulating pattern, opposite to the first side surface, is in contact with a second upper landing pad of the second landing pad structure.

6. The semiconductor device of claim 5, wherein the first lower landing pad and the second upper landing pad do not overlap each other in a horizontal direction.

7. The semiconductor device of claim 5, wherein the first lower landing pad and the second upper landing pad are spaced apart from each other in horizontal and vertical directions.

8. The semiconductor device of claim 1, further comprising:
a metal-semiconductor compound layer between the contact plugs and the lower landing pads of the landing pad structures,
wherein the metal-semiconductor compound layer is on a level lower than that of each of the upper surfaces of the bit line structures.

9. The semiconductor device of claim 1, wherein
each of the bit line structures includes a first conductive layer in contact with the active region and a second conductive layer on the first conductive layer, and
the first conductive layer includes a metal-semiconductor compound.

10. The semiconductor device of claim 9, wherein the first conductive layer is on the bit line trench.

11. The semiconductor device of claim 1, wherein a horizontal width of the insulating pattern increases upwardly.

12. The semiconductor device of claim 1, wherein
the bit line structures have upper surfaces having recesses, respectively, and
the insulating pattern fills one of the recesses.

13. The semiconductor device of claim 1, wherein a horizontal width of each of the bit line structures increases upwardly.

14. The semiconductor device of claim 13, wherein a horizontal width of each of the contact plugs decreases upwardly.

15. The semiconductor device of claim 13, wherein a horizontal width of the lower landing pad decreases upwardly.

16. The semiconductor device of claim 13, further comprising:
spacer structures on side surfaces of the bit line structures, the spacer structures in contact with the contact plugs,
wherein each of the spacer structures has a first horizontal width on a first vertical level, and has a second horizontal width, wider than the first horizontal width, on a second vertical level higher than the first vertical level.

17. A semiconductor device comprising:
a substrate having active regions;
gate structures on the substrate, the gate structures extending across the active regions in a first horizontal direction;
bit line structures extending across the gate structures in a second horizontal direction, intersecting the first horizontal direction;
a contact plug between the bit line structures;
a landing pad structure on the contact plug; and
an insulating pattern in contact with the bit line structures and the landing pad structure, wherein
a central portion of each of the active regions vertically overlaps one of the gate structures,
a first end of each of the active regions vertically overlaps one of the bit line structures, and a second end of each of the active regions, opposite to the first end with respect to the central portion, vertically overlaps the contact plug, and
the landing pad structure includes a lower landing pad, arranged on a level lower than that of each of upper surfaces of the bit line structures, and an upper landing pad on the lower landing pad.

18. The semiconductor device of claim 17, wherein
the bit line structures include a conductive layer including a metal-semiconductor compound, and
the conductive layers are in contact with upper surfaces of the first ends of the active regions.

19. The semiconductor device of claim 17, wherein the contact plug is in contact with an upper surface of a second end of one of the active regions.

20. A semiconductor device comprising:
a substrate having active regions including a first end and a second end;
a gate structure on the substrate, the gate structure extending across the active region in a first horizontal direction;
bit line structures on bit line trenches extending in a second horizontal direction, intersecting the first horizontal direction, the bit line trenches on the first ends across the gate structure;
spacer structures on side surfaces of the bit line structures;
contact plugs between the bit line structures, the contact plugs in contact with side surfaces of the spacer structures and lower surfaces of the second ends;
a metal-semiconductor compound layer on the contact plugs;
landing pad structures on the metal-semiconductor compound layer;
an insulating pattern between the landing pad structures, the insulating pattern in contact with the bit line structures; and
a capacitor structure on the landing pad structures and the insulating pattern, the capacitor structure electrically connected to the landing pad structures, wherein
portions of the bit line structures extend in the second horizontal direction in the bit line trenches, and
each of the landing pad structures includes a lower landing pad, arranged on a level lower than each of upper surfaces of the bit line structures, and an upper landing pad on the lower landing pad.
